(19) United States
(12) Patent Application Publication
(10) Pub. No.: US 2025/0385148 A1
(43) Pub. Date: Dec. 18, 2025

(54) POWER SEMICONDUCTOR DEVICE

(71) Applicant: TONG HSING ELECTRONIC INDUSTRIES, LTD., Taoyuan City (TW)

(72) Inventors: Yu-Ju Kuo, Taoyuan City (TW); Chih-Yu Chung, Taoyuan City (TW); Jia-Yi Wu, Taoyuan City (TW)

(73) Assignee: TONG HSING ELECTRONIC INDUSTRIES, LTD., Taoyuan City (TW)

(21) Appl. No.: 18/795,206

(22) Filed: Aug. 6, 2024

(30) Foreign Application Priority Data
Jun. 18, 2024 (TW) 113122477

(51) Int. Cl. H01L 23/24; H01L 23/00; H01L 23/31; H01L 23/498; H01L 29/16; H01L 29/20; H01L 29/73; H01L 29/739; H01L 29/778; H01L 29/78; H01L 29/861

(52) U.S. Cl. CPC H01L 23/24; H01L 23/3107; H01L 23/49811; H01L 23/49822; H01L 24/48; H01L 2224/48221; H10D 8/00; H10D 10/00; H10D 12/411; H10D 30/47; H10D 30/60; H10D 62/8325; H10D 62/8503

(57) ABSTRACT

A power semiconductor device includes a mounting base; a power chip fixed on the mounting base; a bond wire electrically connecting the power chip to a circuit pattern on the mounting base; a columnar electrode seat disposed on the mounting base; a plastic housing encapsulating an upper surface of the mounting base, the power chip, the bond wire, and the columnar electrode seat. The plastic housing includes a through hole aligned with the columnar electrode seat (e.g. pin holders). An insulating ring is embedded on the surface of the plastic housing and surrounds the through hole. A metal pin is inserted into the through hole and fixed on the columnar electrode seat. The insulating ring and the plastic housing are made of different materials.

### BACKGROUND OF THE INVENTION

### 1. Field of the Invention

The present invention relates to the field of semiconductor technology, and in particular, to an improved power semiconductor device.

### 2. Description of the Prior Art

Power semiconductor devices typically include a power chip and a mounting base that are covered by an encapsulant or a plastic housing, as well as metal pins that extend outward from a certain surface of the encapsulant or plastic housing. Although the encapsulant or plastic housing is made of non-conductive packaging materials or insulating materials, the packaging materials or insulating materials in direct contact with the metal pins still encounter the risk of carbonization due to the large currents or high voltages that flow through or applied to the metal pins. Therefore, the creepage needs to be taken into consideration, which makes the design more difficult.

### SUMMARY OF THE INVENTION

It is one object of the present invention to provide an improved power semiconductor device so as to solve the deficiencies or shortcomings of the existing technology.

One aspect of the invention provides a power semiconductor device including a mounting base comprising a circuit pattern; a power chip mounted on the mounting base; a plurality of bond wires electrically connecting the power chip to the circuit pattern on the mounting base; a plurality of columnar electrode seats (e.g. pin holders) disposed on the mounting base; a plastic housing encapsulating at least an upper surface of the mounting base, the power chip, the plurality of bond wires, and the plurality of columnar electrode seats (e.g. pin holders), wherein the plastic housing comprises a plurality of through holes, respectively aligned with the plurality of columnar electrode seats; a plurality of insulating rings embedded on a first surface of the plastic housing and surround the plurality of through holes, respectively, wherein the plurality of insulating rings and the plastic housing are composed of different materials; and a plurality of metal pins respectively inserted into the plurality of through holes and respectively contacting the plurality of columnar electrode seats.

According to some embodiments, the mounting base comprises a metal lead frame or a ceramic substrate.

According to some embodiments, the power chip comprises an insulated gate bipolar transistor, a power metal-oxide-semiconductor field-effect transistor, a bipolar junction transistor, a silicon carbide power device, a gallium nitride power device, a high electron mobility transistor, or a fast recovery diode.

According to some embodiments, the plastic housing comprises a thermoplastic resin material.

According to some embodiments, a bottom of the mounting base is exposed from a second surface of the plastic housing opposite to the first surface.

According to some embodiments, the insulating ring is made of insulating and non-carbonizable material.

According to some embodiments, the insulating ring is made of insulating inorganic material.

According to some embodiments, the insulating inorganic material comprises molten glass or ceramic material.

According to some embodiments, one end of each of the plurality of metal pins is inserted into and electrically connected to each of the plurality of columnar electrode seats, and the other end of each of the plurality of metal pins protrudes from the first surface of the plastic housing for further connection with an external circuit.

According to some embodiments, the plurality of columnar electrode seats is fixed on the mounting base by welding.

Another aspect of the invention provides a power semiconductor device including a mounting base comprising a circuit pattern; a power chip mounted on the mounting base; a plurality of bond wires electrically connecting the power chip to the circuit pattern on the mounting base; a plurality of metal pins electrically connected to the mounting base and the power chip; an encapsulant encapsulating an upper surface of the mounting base, the power chip, the plurality of bond wires, and one end of each of the plurality of metal pins adjacent to the mounting base, wherein the other end of each of the plurality of metal pins protrudes from an end surface of the encapsulant for further connection with an external circuit, wherein the plurality of metal pins protruding from the end surface of the encapsulant comprises an inactive zone and an effective zone; and an insulating layer disposed in proximity to the end surface of the encapsulant and surrounding the inactive zone of the plurality of metal pins.

According to some embodiments, the mounting base comprises a metal lead frame or a ceramic substrate.

According to some embodiments, the power chip comprises an insulated gate bipolar transistor, a power metal-oxide-semiconductor field-effect transistor, a bipolar junction transistor, a silicon carbide power device, a gallium nitride power device, a high electron mobility transistor, or a fast recovery diode.

According to some embodiments, the encapsulant comprises a thermosetting resin material.

According to some embodiments, the insulating layer and the encapsulant are composed of different materials.

According to some embodiments, the insulating layer is composed of an insulating and non-carbonizable material.

According to some embodiments, the insulating layer is composed of an insulating inorganic material.

According to some embodiments, the insulating inorganic material comprises molten glass or ceramic material.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view of a power semiconductor device according to an embodiment of the present invention.

FIG. 2 is a side view of a power semiconductor device according to another embodiment of the present invention.

FIG. 3 is a schematic cross-sectional view taken along line I-I′ in FIG. 2.

### DETAILED DESCRIPTION

The following is a specific example to illustrate the implementation of the “power semiconductor device” disclosed in the present invention. Those skilled in the art can understand the advantages and effects of the present invention from the content disclosed in this specification. The present invention can be implemented or applied through other different specific embodiments, and various details in this specification can also be modified and changed based on different viewpoints and applications without departing from the concept of the present invention. In addition, the drawings of the present invention are only simple schematic illustrations and are not depictions based on actual dimensions, as is stated in advance. The following embodiments will further describe the relevant technical content of the present invention in detail, but the disclosed content is not intended to limit the scope of the present invention.

It should be understood that although terms such as “first”, “second” and “third” may be used herein to describe various elements or signals, these elements or signals should not be limited by these terms. These terms are primarily used to distinguish one component from another component or one signal from another signal. In addition, the term “or” used in this article shall include any one or combination of more of the associated listed items depending on the actual situation.

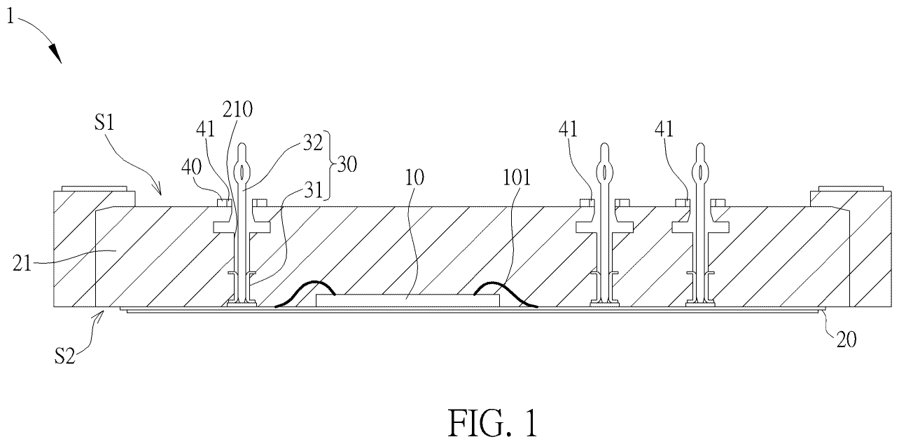

Please refer to FIG. 1, which is a schematic cross-sectional view of a power semiconductor device according to an embodiment of the present invention. As shown in FIG. 1, the power semiconductor device 1 includes a mounting base 20 and at least one power chip 10 fixed on the mounting base 20. According to an embodiment of the present invention, the mounting base 20 may have a circuit pattern. According to an embodiment of the present invention, for example, the mounting base 20 may include a metal lead frame or a ceramic substrate, but is not limited thereto. According to an embodiment of the present invention, for example, the power chip 10 can be electrically connected to the circuit pattern on the mounting base 20 through a plurality of bond wires 101, such as gold wires or copper wires, but is not limited thereto.

According to an embodiment of the present invention, the type of the power chip 10 can be adjusted and changed according to actual needs. For example, the power chip 10 may be an insulated gate bipolar transistor (IGBT), a power metal oxide semi-field effect transistor (power MOSFET), a bipolar Junction Transistor (BJT), a silicon carbide (SiC) power device, a gallium nitride (GaN) power device, a high electron mobility transistor (HEMT), or a fast recovery diode (FRD).

According to an embodiment of the present invention, a plurality of columnar electrode seats (e.g. pin holders) 31 is provided on the mounting base 20. According to an embodiment of the present invention, for example, the columnar electrode seats 31 may be made of copper or copper alloy, but is not limited thereto. According to an embodiment of the present invention, for example, the columnar electrode seats (e.g. pin holders) 31 may be fixed on the mounting base 20 by welding or other methods. According to an embodiment of the present invention, the power semiconductor device 1 further includes a plastic housing 21 that covers at least the upper surface of the mounting base 20, the power chip 10 fixed on the mounting base 20, the bond wires 101 and the columnar electrode seats (e.g. pin holders) 31.

According to an embodiment of the present invention, for example, the plastic housing 21 may include a thermoplastic resin material, but is not limited thereto. According to an embodiment of the present invention, for example, the plastic housing 21 may be formed using injection molding techniques. According to an embodiment of the present invention, for example, the plastic housing 21 may be formed using insert molding techniques. According to an embodiment of the present invention, the plastic housing 21 includes a plurality of through holes 210 respectively aligned with the plurality of columnar electrode seats 31.

According to an embodiment of the present invention, the through holes 210 are provided on the first surface S1 of the plastic housing 21. When the power semiconductor device 1 is subsequently installed on a circuit board, the first surface S1 directly faces the circuit board. According to an embodiment of the present invention, the bottom of the mounting base 20 may be exposed from the second surface S2 of the plastic housing 21 opposite to the first surface S1. According to an embodiment of the present invention, the plastic housing 21 may further include a plurality of integrally formed annular structures 40 on the first surface S1, respectively corresponding to the plurality of through holes 210. According to an embodiment of the present invention, an insulating ring 41 is bonded in the inner edge of each of the annular structures 40 by insert molding. The insulating ring 41 is located at the top of the through hole 210. In some embodiments, the annular structure 40 and the insulating ring 41 may not protrude from the first surface S1 of the plastic housing 21.

According to an embodiment of the present invention, the insulating ring 41 and the annular structure 40 are made of different materials. According to an embodiment of the present invention, for example, the insulating ring 41 may be made of an insulating and non-carbonizable material, preferably an insulating inorganic material, such as molten glass or ceramic material.

According to an embodiment of the present invention, the power semiconductor device 1 further includes a plurality of metal pins 32 which are respectively inserted into the plurality of through holes 210 on the first surface S1 of the plastic housing 21. According to an embodiment of the present invention, one end of each metal pin 32 is inserted into the corresponding columnar electrode seat 31 through the through hole 210 and is electrically connected to the columnar electrode seat 31, while the other end of the metal pin 32 protrudes from the first surface S1 of the plastic housing 21 for further connection with external circuits. According to an embodiment of the present invention, the columnar electrode seat 31 and the metal pin 32 together constitute a terminal 30 of the power semiconductor device 1.

One technical feature of the present invention is that an insulating ring 41 is embedded in each through hole 210 on the first surface S1 of the plastic housing 21. The insulating ring 41 is spaced a certain distance away from the metal pin 32 and surrounds the metal pin 32. Since the insulating ring 41 is made of insulating and non-carbonizable material, even if the metal pin 32 is tilted or deformed causing it to directly contact the insulating ring 41, no creepage phenomenon will occur. Therefore, there is no need to consider the creepage in the design, and the present invention can be applied to existing products operated at voltages greater than 1200V.

In addition, the injection molding techniques can be used to manufacture the plastic housing 21, and only the existing mold needs to be modified to make room for the placement of the insulating ring, without scrapping the existing mold, thereby saving costs.

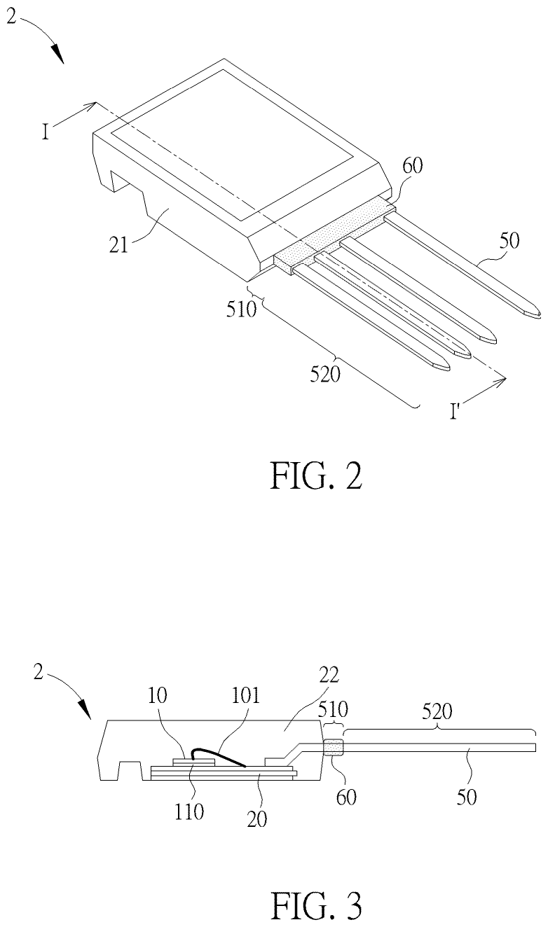

Please refer to FIG. 2 and FIG. 3. FIG. 2 is a side view of a discrete power semiconductor device according to another embodiment of the present invention, and FIG. 3 is a schematic cross-sectional view taken along line I-I′ in FIG. 2, wherein like materials, layers or regions are designated by like numeral numbers or labels.

As shown in FIG. 2 and FIG. 3, the power semiconductor device 2 includes a mounting base 20, at least one power chip 10, bond wires 101, an encapsulant (for example, a molding compound) 22 and metal pins 50. According to an embodiment of the present invention, the mounting base 20 may have a circuit pattern. According to an embodiment of the present invention, for example, the mounting base 20 may include a metal lead frame or a ceramic substrate, but is not limited thereto. According to an embodiment of the present invention, for example, the power chip 10 can be electrically connected to the circuit pattern on the mounting base 20 through a bond wire 101, such as a gold wire or a copper wire, but is not limited thereto. According to an embodiment of the present invention, for example, the power chip 10 can be fixed on the mounting base 20 through the soldering layer 110, but is not limited thereto.

According to an embodiment of the present invention, the type of the power chip 10 can be adjusted and changed according to actual needs. For example, the power chip 10 may be an insulated gate bipolar transistor (IGBT), a power metal oxide semi-field effect transistor (power MOSFET), a bipolar Junction Transistor (BJT), a silicon carbide (SiC) power device, a gallium nitride (GaN) power device, a high electron mobility transistor (HEMT), or a fast recovery diode (FRD).

According to an embodiment of the present invention, one end of the metal pin 50 may be fixed on the mounting base 20. According to an embodiment of the present invention, the encapsulant 22 encapsulates the upper surface of the mounting base 20, the power chip 10, the bond wires 101 and part of the metal pins 50 adjacent to the mounting base 20. According to an embodiment of the present invention, the other end of the metal pin 50 protrudes from one end surface of the encapsulant 22 to connect with an external circuit.

According to an embodiment of the present invention, for example, the encapsulant 22 may include a thermosetting resin material, but is not limited thereto. According to an embodiment of the present invention, for example, the encapsulant 22 may be formed by using transfer molding techniques.

According to an embodiment of the present invention, the metal pin 50 protruding from one end surface of the encapsulant 22 comprises an inactive zone 510 and an effective zone 520. The inactive zone 510 is, for example, a dam bar, which is the region closer to the end surface of the encapsulant 22. When the power semiconductor device 2 is mounted to a corresponding socket member, only the metal pins 50 in the effective zone 520 function.

According to an embodiment of the present invention, the power semiconductor device 2 further includes an insulating layer 60, which is disposed in proximity to the end surface of the encapsulant 22 and surrounds the inactive zone 510 of the metal pin 50. According to an embodiment of the present invention, the insulating layer 60 may be strip-shaped, but is not limited thereto. According to an embodiment of the present invention, the insulating layer 60 and the encapsulant 22 are made of different materials. According to an embodiment of the present invention, the insulating layer 60 may be composed of an insulating and non-carbonizable material, preferably an insulating inorganic material, such as molten glass or ceramic material. Since the insulating layer 60 is made of insulating and non-carbonizable materials, the creepage distance between the metal pins 50 can be increased.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A power semiconductor device, comprising:
a mounting base comprising a circuit pattern;
a power chip mounted on the mounting base;
a plurality of bond wires electrically connecting the power chip to the circuit pattern on the mounting base;
a plurality of columnar electrode seats disposed on the mounting base;
a plastic housing encapsulating at least an upper surface of the mounting base, the power chip, the plurality of bond wires, and the plurality of columnar electrode seats, wherein the plastic housing comprises a plurality of through holes, respectively aligned with the plurality of columnar electrode seats;
a plurality of insulating rings embedded on a first surface of the plastic housing and surround the plurality of through holes, respectively, wherein the plurality of insulating rings and the plastic housing are composed of different materials; and
a plurality of metal pins respectively inserted into the plurality of through holes and respectively contacting the plurality of columnar electrode seats.

2. The power semiconductor device according to claim 1, wherein the mounting base comprises a metal lead frame or a ceramic substrate.

3. The power semiconductor device according to claim 1, wherein the power chip comprises an insulated gate bipolar transistor, a power metal-oxide-semiconductor field-effect transistor, a bipolar junction transistor, a silicon carbide power device, a gallium nitride power device, a high electron mobility transistor, or a fast recovery diode.

4. The power semiconductor device of claim 1, wherein the plastic housing comprises a thermoplastic resin material.

5. The power semiconductor device of claim 1, wherein a bottom of the mounting base is exposed from a second surface of the plastic housing opposite to the first surface.

6. The power semiconductor device according to claim 1, wherein the insulating ring is made of insulating and non-carbonizable material.

7. The power semiconductor device according to claim 1, wherein the insulating ring is made of insulating inorganic material.

8. The power semiconductor device according to claim 7, wherein the insulating inorganic material comprises molten glass or ceramic material.

9. The power semiconductor device according to claim 1, wherein one end of each of the plurality of metal pins is inserted into and electrically connected to each of the plurality of columnar electrode seats, and the other end of each of the plurality of metal pins protrudes from the first surface of the plastic housing for further connection with an external circuit.

10. The power semiconductor device according to claim 1, wherein the plurality of columnar electrode seats are fixed on the mounting base by welding.

11. A power semiconductor device, comprising:
a mounting base comprising a circuit pattern;
a power chip mounted on the mounting base;
a plurality of bond wires electrically connecting the power chip to the circuit pattern on the mounting base;
a plurality of metal pins electrically connected to the mounting base and the power chip;
an encapsulant encapsulating an upper surface of the mounting base, the power chip, the plurality of bond wires, and one end of each of the plurality of metal pins adjacent to the mounting base, wherein the other end of each of the plurality of metal pins protrudes from an end surface of the encapsulant for further connection with an external circuit, wherein the plurality of metal pins protruding from the end surface of the encapsulant comprises an inactive zone and an effective zone; and
an insulating layer disposed in proximity to the end surface of the encapsulant and surrounding the inactive zone of the plurality of metal pins.

12. The power semiconductor device according to claim 11, wherein the mounting base comprises a metal lead frame or a ceramic substrate.

13. The power semiconductor device according to claim 11, wherein the power chip comprises an insulated gate bipolar transistor, a power metal-oxide-semiconductor field-effect transistor, a bipolar junction transistor, a silicon carbide power device, a gallium nitride power device, a high electron mobility transistor, or a fast recovery diode.

14. The power semiconductor device according to claim 11, wherein the encapsulant comprises a thermosetting resin material.

15. The power semiconductor device according to claim 11, wherein the insulating layer and the encapsulant are composed of different materials.

16. The power semiconductor device according to claim 11, wherein the insulating layer is composed of an insulating and non-carbonizable material.

17. The power semiconductor device according to claim 11, wherein the insulating layer is composed of an insulating inorganic material.

18. The power semiconductor device according to claim 17, wherein the insulating inorganic material comprises molten glass or ceramic material.
